(19) United States
(12) Patent Application Publication
(10) Pub. No.: US 2023/0162540 A1
(43) Pub. Date: May 25, 2023

(54) Method, Device, Computer Program and Computer-Readable Storage Medium for Generating a Graph Database for Determining a Part to be Checked of a Mechatronic System

(71) Applicant: Bayerische Motoren Werke Aktiengesellschaft, Muenchen (DE)

(72) Inventors: Melissa Gresser, Muenchen (DE); Dominik Brehl, Muenchen (DE)

(21) Appl. No.: 17/916,968

(22) PCT Filed: Mar. 1, 2021
(86) PCT No.: PCT/EP2021/054996

§ 371 Date: Oct. 4, 2022

(30) Foreign Application Priority Data
Apr. 27, 2020 (DE) 10 2020 111 339.0

(51) Int. Cl. G07C 5/08; G06F 16/901

(52) U.S. Cl. CPC G07C 5/0808; G06F 16/9024

(57) ABSTRACT

A method for determining a part to be checked of a mechatronic system includes providing a graph database having at least one first sub-level with first nodes, a second sub-level with second nodes, a third sub-level with third nodes and a fourth sub-level with fourth nodes, wherein directly adjacent sub-levels are connected by directed edges. The method also includes determining at least one of the fourth nodes which is output as faulty during a check of the mechatronic system, and inverting the directed edges. The method further includes determining at least one first node to be checked of the first nodes which is representative of at least one of the group consisting of at least one component and at least one part of the mechatronic system, starting from the determined fourth node, depending on a range.

The present application is the U.S. national phase of PCT Application PCT/EP2021/054996 filed on Mar. 1, 2021, which claims priority of German patent application No. 102020111339.0 filed on Apr. 27, 2020, which is incorporated herein by reference in its entirety.

### TECHNICAL FIELD

The present disclosure relates generally to the field of mechatronic systems, and more particular, to determining a part of a mechatronic system to be checked.

### BACKGROUND

A mechatronic system can be a system designed to operate and/or to control a vehicle. A mechatronic system can be subdivided into a large number of subsystems. Each subsystem can be, for example, assigned a large number of components. These components can each comprise a large number of parts. The mechatronic system therefore comprises a coarse-grained level which, for example, corresponds to the subsystems, and a fine-grained level which corresponds to the parts.

The parts of a mechatronic system generally communicate with one another. Many of these parts therefore depend on one another. This means that, for example, an output signal of one of the parts is used as an input signal of another part.

At least some of the parts can be electrical parts, such as actuators and/or sensors. Furthermore, it is possible that at least several of the parts are virtual parts. The virtual parts are each, for example, a software application. Each of the parts can also be assigned a corresponding function. If, for example, a part is faulty, the faulty part can exhibit a malfunction. This malfunction can, for example, be stored as a measured variable of the mechatronic system. The measured variable of the mechatronic system is, for example, on-board or off-board data and/or any type of prose nomenclature. For example, the measured variable of the mechatronic system is representative of a fault memory entry and/or a customer observation.

It would be desirable to simply and efficiently determine a part of a mechatronic system to be checked. Furthermore, it would be desirable to have a device and a computer program which can simply and efficiently determine a part of a mechatronic system to be checked.

### SUMMARY

These objects are achieved by at least some embodiments described herein.

Firstly, the method for determining a part to be checked of a mechatronic system will be explained. The mechatronic system is, for example, integrated in a vehicle.

The vehicle is, for example, a motor vehicle, such as an automobile, truck, a transporter and/or a motorcycle. Alternatively, the vehicle can be an aircraft or a watercraft.

All the parts, functions, malfunctions and/or measured variables of a mechatronic system can be represented, for example, in the form of a graph. In this case, each part, each function, each malfunction and/or each measured variable of the mechatronic system is representative of a node of the graph.

According to at least one embodiment of the method, a graph database having at least one first sub-level with first nodes, a second sub-level with second nodes, a third sub-level with third nodes and a fourth sub-level with fourth nodes is provided.

The graph database provided in this case comprises a first main level and a second main level. The first main level comprises the first sub-level and the second sub-level. In addition, the second main level comprises the third sub-level and the fourth sub-level.

According to at least one embodiment of the method, directly adjacent sub-levels are each connected to one another by first, second or third directed edges.

In this embodiment, the first nodes and the second nodes are connected by the first directed edges. At least one subset of the first directed edges can be directed from the first sub-level to the second sub-level, and the remaining subset of the first edges can be directed from the second sub-level to the first sub-level.

The directed second edges are, for example, directed from the second sub-level in the direction of the third sub-level. The directed third edges are, for example, directed from the third sub-level to the fourth sub-level.

The second directed edges therefore also connect the first main level to the second main level.

According to at least one embodiment of the method, at least one of the fourth nodes which is output as faulty during a check of the mechatronic system is determined. For example, the checking can be carried out in a workshop.

According to at least one embodiment of the method, the directed edges are inverted. During such an inversion, a direction of the edges is reversed.

After the inversion, the subset of the first directed edges which, before the inversion, are directed from the first sub-level to the second sub-level, is, for example, directed from the second sub-level to the first sub-level. The remaining subset of the first edges is, for example, directed from the second sub-level to the first sub-level after the inversion.

After the inversion, the directed second edges are, for example, directed from the third sub-level in the direction of the second sub-level. The third directed edges are, for example, directed from the fourth sub-level to the third sub-level.

According to at least one embodiment of the method, at least one first node to be checked of the first nodes which is representative of at least one component and/or at least one part of the mechatronic system is determined, starting from the determined fourth node, depending on a range.

In this embodiment, the determined fourth nodes are each an entry point of a query of the graph database. Via a “backward reachability analysis” and the predefined range, a set of ancestors of the respective nodes is considered. The range can be selected as a function of the attribution of the nodes and edges of the ancestors of the respective fourth nodes.

This set of ancestors indicates, for example, how an error propagation is related. For example, an intersection set of the ancestors of the first nodes represents the set of first nodes which are linked via active relationships and thus confirms a potential relationship between the determined fourth nodes and the first nodes.

In the event that no first nodes are included in the intersection set, the fourth nodes are to be differentiated in time in order to consider the possibility of multiple error causes. Via logical operations, a solution set of at least one first node is generated therefrom.

According to at least one embodiment of the method, the range is predefined as a function of the edges.

By using such a method, for example in workshops, a checking plan, i.e. which parts must be checked, is created automatically as a function of the fourth nodes, in particular the measured variable of the mechatronic system. The determined fourth nodes which are output as faulty during a check of the mechatronic system, in addition to the aforementioned customer effects, are used as “entry points” into the graph. By means of the method described here, the first nodes of those components and/or parts, the failure of which explains the set of determined fourth nodes, are returned. The relevant first nodes can then be output, so that a set of fault candidates is effectively reduced and a checking plan based thereon can be created.

According to at least one embodiment of the method, the edges each comprise at least one attribute. The attribute is, for example, a unique identifier of the part, function, malfunction and/or measured variable of the mechatronic system that is associated with the respective node.

The attributes of the edges can additionally comprise repair costs, repair time and/or replacement frequency. Therefore, the query according to the present method is a dynamic output to first nodes to be checked, in particular parts to be checked. Furthermore, the output can comprise an action recommendation in order to limit first nodes to be checked efficiently, in particular parts to be checked. Therefore, a particularly efficient checking plan of a mechatronic system to be checked can be derived.

According to at least one embodiment of the method, the second nodes are each representative of at least one function of a component associated with the function and/or of a part associated with the function.

According to at least one embodiment of the method, in the graph database at least one of the first nodes is connected to at least one of the second nodes by one of the first directed edges.

According to at least one embodiment of the method, the first directed edge is representative of an active relationship between the first node and the second node.

According to at least one embodiment of the method, the third nodes are each representative of at least one malfunction of a function associated with the malfunction.

According to at least one embodiment of the method, in the graph database at least one of the second nodes is connected to one of the third nodes by one of the second directed edges.

According to at least one embodiment of the method, the second directed edge is representative of an active relationship between the second node and the third node.

According to at least one embodiment of the method, the fourth nodes are each representative of at least one measured variable of the mechatronic system of a malfunction associated with the measured variable of the mechatronic system. The measured variable from the mechatronic system is, for example, a fault memory entry and/or a diagnostic function.

The fault memory entry or the diagnostic function is, for example, an identification number for the identification of malfunctions, for example a diagnostic trouble code “DTC” for short), and/or at least one customer observation.

According to at least one embodiment of the method, in the graph database at least one of the third nodes is connected to one of the fourth nodes by one of the third directed edges.

In addition, a device for generating a graph database for determining at least one faulty part of a mechatronic system is specified.

The device is designed to carry out the method described here. All the features of the embodiment disclosed in conjunction with the method are therefore also disclosed in conjunction with the device and vice versa.

Furthermore, a vehicle which has the device described here is specified. The vehicle is in particular a motor vehicle.

In addition, a computer program is specified, comprising commands which, during the execution of the computer program by a computer, cause the latter to carry out the method described here.

Also specified is a computer-readable storage medium on which the computer program described here is stored.

### BRIEF DESCRIPTION OF THE DRAWINGS

Exemplary embodiments of the invention are explained in more detail below by using the schematic drawings, in which:

FIG. 1 shows a flowchart of a method according to an exemplary embodiment,

FIG. 2 shows a schematic representation of a device and a vehicle according to an exemplary embodiment,

FIG. 3 shows an illustration of a graph database according to an exemplary embodiment, and

FIG. 4 shows a schematic representation of a query of a graph database according to an exemplary embodiment.

### DETAILED DESCRIPTION

Elements of the same design or function are identified by the same designations over all the figures.

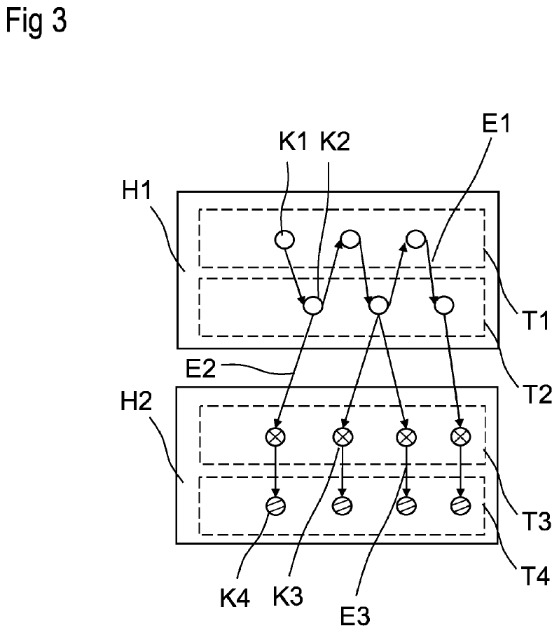

In the flowchart of the method according to the exemplary embodiment of FIG. 1, firstly a method step S1 is carried out, in which a graph database 1 having a first sub-level T1 with first nodes K1, a second sub-level T2 with second nodes K2, a third sub-level with third nodes K3 and a fourth sub-level with fourth nodes K4 is provided. Here, directly adjacent sub-levels T1, T2, T3, T4 are each connected to one another by first, second or third directed edges E1, E2, E3. A graph database 1 of this type is explained in more detail by way of example in conjunction with FIG. 3.

The first nodes K1 are each representative of at least one component 3 and/or at least one part 2 of a mechatronic system 4. The second nodes K2 are each representative of at least one function of a component 3 associated with the function and/or of a part 2 associated with the function. The third nodes K3 are each representative of at least one malfunction of a function associated with the malfunction, and the fourth nodes K4 are each representative of at least one measured variable of the mechatronic system of a malfunction associated with the measured variable of the mechatronic system.

Here, the measured variable of the mechatronic system is a fault memory entry, such as a DTC.

In a following method step S2, at least one of the fourth nodes K4 which is output as faulty during a check of the mechatronic system 4 is determined.

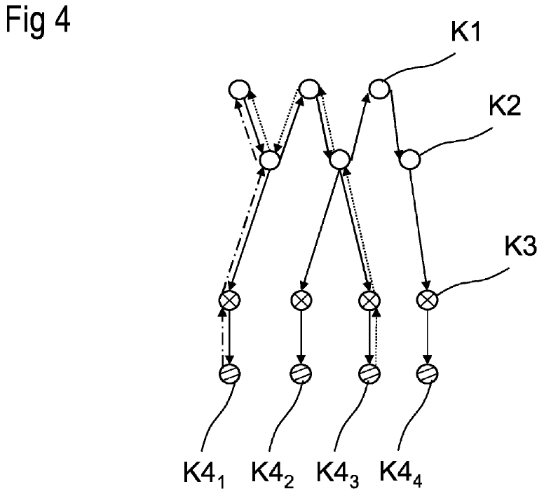

In the further method step S3, the directed edges E1, E2, E3 are then inverted. The inversion and an alignment of the edges E1, E2, E3 are explained in more detail in conjunction with FIG. 4.

Subsequently, in a method step S4, at least one first node K1 to be checked of the first nodes K1 which is representative of at least one component 3 and/or at least one part 2 of the mechatronic system 4 is determined. This first node K1 to be checked is determined as a function of a range, starting from the determined fourth node K4.

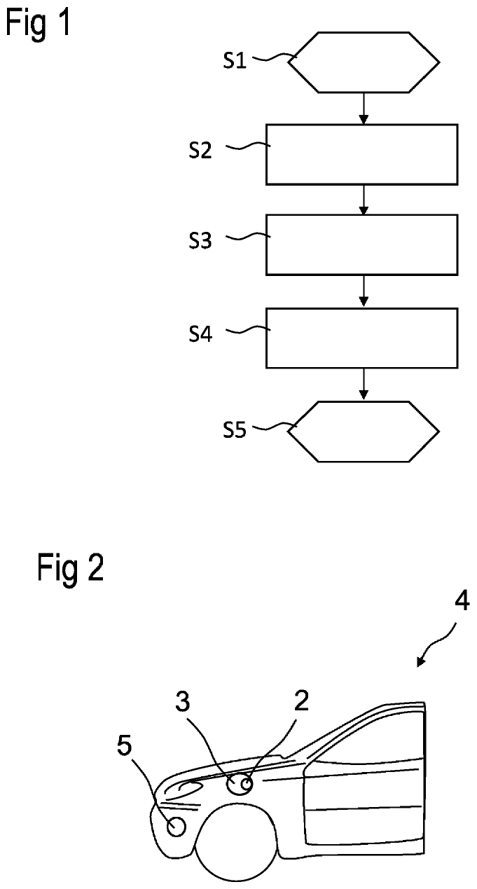

The vehicle 6 according to the exemplary embodiment of FIG. 2 comprises a device 5. The device 5 is designed to carry out the method described here. The device 5 can be part of the vehicle 6. Alternatively, it is possible that the device 5 is encompassed by an external device. Here, the external device is not part of the vehicle 6. In addition, it is possible that the device 5 is part of the vehicle 6 and part of the external device.

The vehicle 6 in this exemplary embodiment is a motor vehicle. The vehicle 6 further comprises the mechatronic system 4, which has at least one component 3 and at least one part 2.

The graph database 1 according to FIG. 3 comprises a first main level H1 and a second main level H2. The first main level H1 also comprises a first sub-level T1 and a second sub-level T2. The first nodes K1 are located in the first sub-level T1. Furthermore, the second nodes K2 are located in the second sub-level T2. The first nodes K1 and the second nodes K2 are connected by the first directed edges E1. At least one subset of the first directed edges E1 can be directed from the first sub-level T1 to the second sub-level T2, and the remaining subset of the first edges E1 can be directed from the second sub-level T2 to the first sub-level T1.

In addition, the second main level H2 comprises a third sub-level T3 and a fourth sub-level T4. The second main level H2 is the fault level of the graph database 1. The third nodes K3 are arranged in the third sub-level T3, and the fourth nodes K4 are arranged in the fourth sub-level T4. The directed second edges E2 are directed from the second sub-level T2 in the direction of the third sub-level T3. The third edges E3 are directed from the third sub-level T3 to the fourth sub-level T4.

According to FIG. 4, the subset of the first directed edges E1 which, before the inversion, are directed from the first sub-level T1 to the second sub-level T2, are directed from the second sub-level T2 to the first sub-level T1 after the inversion. The remaining subset of the first edges E1 is directed from the second sub-level T2 to the first sub-level TI after the inversion.

After the inversion, the directed second edges E2 are directed from the third sub-level T3 in the direction of the second sub-level T2. The third directed edges E3 are directed from the fourth sub-level T4 to the third sub-level T3.

If, for example, the fourth node K4₁ is used as an entry point, then the method results in the determination of the first node K1₁ to be checked of the first nodes.

If, for example, the fourth node K4₁ and the fourth node K4₃ are used as entry points, then the method results in the determination of the common intersection set of the first nodes to be checked, that is to say likewise the first node K1₁.

### LIST OF DESIGNATIONS

1 Graph database
2 Part
3 Component
4 Mechatronic system
5 Device
6 Vehicle
K1 First node
K2 Second node
K3 Third node
K4 Fourth node
E1 First edge
E2 Second edge
E3 Third edge
E4 Further third edge
H1 First main level
H2 Second main level
T1 First sub-level
T2 Second sub-level
T3 Third sub-level
T4 Fourth sub-level

1.-9. (canceled)

10. A method for determining a part to be checked of a mechatronic system, comprising
providing a graph database having at least one first sub-level with first nodes, a second sub-level with second nodes, a third sub-level with third nodes and a fourth sub-level with fourth nodes, wherein directly adjacent sub-levels are connected by directed edges,
determining at least one of the fourth nodes which is output as faulty during a check of the mechatronic system,
inverting the directed edges,
determining at least one first node to be checked of the first nodes which is representative of at least one of the group consisting of at least one component and at least one part of the mechatronic system, starting from the determined fourth node, depending on a range.

11. The method as claimed in claim 10, wherein the range is predefined as a function of the directed edges.

12. The method as claimed in claim 11, wherein each of the directed edges comprises at least one attribute.

13. The method as claimed in claim 10, wherein each of the directed edges comprises at least one attribute.

14. The method as claimed in claim 10, wherein:
each of the second nodes is representative of at least one function of at least one of the group consisting of a component associated with the function and a part associated with the function,
in the graph database at least one of the first nodes is connected to at least one of the second nodes by a first directed edge of the directed edges, and
the first directed edge is representative of an active relationship between the first node and the second node.

15. The method as claimed in claim 14, wherein:
each of the third nodes is representative of at least one malfunction of a function associated with the malfunction,
in the graph database at least one of the second nodes is connected to one of the third nodes by a second directed edge of the directed edges, and
the second directed edge is representative of an active relationship between the second node and the third node.

16. The method as claimed in claim 15, wherein:
each of the fourth nodes is representative of at least one measured variable of the mechatronic system of a malfunction associated with the measured variable of the mechatronic system, and
in the graph database at least one of the third nodes is connected to one of the fourth nodes by a third directed edge of the directed edges.

17. The method as claimed in claim 16, wherein the range is predefined as a function of the directed edges.

18. The method as claimed in claim 17, wherein each of the directed edges comprises at least one attribute.

19. The method as claimed in claim 16, wherein each of the directed edges comprises at least one attribute.

20. The method as claimed in claim 15, wherein the range is predefined as a function of the directed edges.

21. The method as claimed in claim 20, wherein each of the directed edges comprises at least one attribute.

22. The method as claimed in claim 14, wherein the range is predefined as a function of the directed edges.

23. The method as claimed in claim 22, wherein each of the directed edges comprises at least one attribute.

24. The method as claimed in claim 10, wherein:
each of the third nodes is representative of at least one malfunction of a function associated with the malfunction,
in the graph database at least one of the second nodes is connected to one of the third nodes by one of the directed edges, and
the one of the directed edges is representative of an active relationship between the second node and the third node.

25. A device for generating a graph database for determining at least one faulty part of a mechatronic system, which is designed to carry out the method as claimed in claim 10.

26. A computer program comprising commands which, during the execution of the computer program by a computer, cause the latter to carry out the method as claimed in claim 10.

27. The computer program as claimed in claim 26, wherein the range is predefined as a function of the directed edges.

28. The computer program as claimed in claim 27, wherein each of the directed edges comprises at least one attribute.

29. A computer-readable storage medium on which the computer program as claimed in claim 26 is stored.
